(19) United States
(12) Patent Application Publication
(10) Pub. No.: US 2012/0318322 A1
(43) Pub. Date: Dec. 20, 2012

(54) SOLAR PANEL MOUNTING SYSTEM

(75) Inventors: Samuel Ross Garland Lanyon, Elwood (AU); Stuart Elliott, Park Orchards (AU); Eduardo Vom, Brunswick East (AU); Richard Allman, Wyndham Vale (AU)

(73) Assignee: EMPIRE TECHNOLOGY DEVELOPMENT LLC, Wilmington, DE (US)

(21) Appl. No.: 13/581,204

(22) PCT Filed: Jun. 11, 2010
(86) PCT No.: PCT/AU2010/000728

§ 371 Date: Aug. 24, 2012

(30) Foreign Application Priority Data
Feb. 25, 2010 (AU) 2010200700

(51) Int. Cl. H01L 31/042; B23P 11/00

(52) U.S. Cl. 136/244; 29/428

(57) ABSTRACT

Solar energy collecting panels, mounting systems for solar energy collecting panels, and techniques for mounting the solar energy collecting panels are disclosed. A mounting system for solar energy collecting panels includes a base assembly having rails securable to an underlying structure. The rails include panel mountings configured to receive mounting assemblies of the panels for mounting the panels to the rails so that in use each rail has mounted to it multiple panels whilst each panel is mounted to two or more of the rails.

### TECHNICAL FIELD

This disclosure relates generally to mounting systems for solar energy collectors, solar energy collecting systems and solar energy panels. While the disclosure is directed to mounting photovoltaic (PV) panels to residential and commercial roofs, it is not limited to such installations, and the mounting systems may be used with other types of collectors (such as solar thermal collectors) or for mounting on other substrates, such as the ground.

### BACKGROUND

PV panels typically include an array of electrically connected PV cells. One inhibiting factor for the uptake of PV panels in residential power generation applications is the relatively higher cost compared with the cost of power provided by utility companies. A high portion of the overall cost is installation cost, which typically accounts for more than about 20% of the overall cost. Furthermore, where PV panels need to be inclined with respect to the roof pitch to improve incidence to the sun (e.g., when installed on a flat roof), mounting systems in such applications can represent about 10-15% of the overall cost of the system.

### SUMMARY OF INVENTION

In one embodiment, a mounting system for solar energy collecting panels includes a base assembly having rails securable to an underlying structure. The system further include panel mountings configured to receive mounting assemblies of the panels for mounting the panels to the rails so that in use each rail has mounted to it multiple panels whilst each panel is mounted to two or more of the rails.

In another embodiment, a mounting system for solar energy collecting panels includes a base assembly securable to an underlying structure, panel mountings for mounting the panels to the base assembly, and a panel support assembly to support the panels in one or more inclined angles relative to the base assembly.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 shows a schematic of a residential building with an illustrative embodiment of a solar collecting system mounted on its roof;

FIG. 2 shows a side elevation of the solar collecting system shown in FIG. 1;

FIG. 3 shows a schematic of an illustrative embodiment of a mounting rail used in the solar collecting system of FIG. 1;

FIG. 4 shows a detailed exploded view of an illustrative embodiment of a connection between a mounting rail and a PV panel;

FIG. 5 shows a side elevation of the connection shown in FIG. 4, with an illustrative embodiment of a locking plate installed;

FIG. 6 shows a detailed schematic of an illustrative embodiment of a connection of a PV panel to the mounting rail and a support to hold the panel at an inclined angle to the rail;

FIG. 7 shows a rear view of the connection shown in FIG. 6; and

FIG. 8 shows an exploded view of an illustrative embodiment of an orientation rail used in the solar collecting system.

### DETAILED DESCRIPTION OF THE INVENTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

This disclosure is directed generally to mounting systems for solar collectors (also known as “solar panels” or “solar energy collecting panels”) in the form of photovoltaic (PV) panels. While the disclosure is described generally in the context of systems for mounting PV panels to residential and commercial roofs, it is not limited to such installations, and may be used for mounting on other substrates, such as the ground.

PV panels typically include an array of electrically connected PV cells. Common PV cells are made from monocrystalline cells, or polycrystalline cells. Monocrystalline cells include wafer-based cells of crystalline silicon, which are cut from a cylinder of a single silicon crystal. Polycrystalline cells are cut from ingots of molten and recrystallised silicon. Polycrystalline cells are cheaper to manufacture than monocrystalline cells, yet less efficient. Another increasingly common type of PV cell is the thin-film PV cell (TFPVC). TFPVCs are made by deposition of a photovoltaic material, such as amorphous silicon, on an appropriate substrate, such as glass, plastic or metal. TFPVCs tend to be cheaper yet less efficient that monocrystalline or polycrystalline based PV cells.

Currently, solar cell sizes are limited as a function of manufacturing restrictions and cost per mm². PV cells tend to be square, to improve packing in an array, with dimensions ranging from approximately 100 mm×100 mm to approximately 150 mm×150 mm. There currently is no industry standard for the dimensions of a PV cell, or the number of cells in an array forming a PV panel. However, for commercial power generation systems, typical PV panel dimensions are approximately 650 mm×1500 mm, or 900 mm×1800 mm, depending on the PV cell size and the manufacturer. For example, a PV panel may comprise a 6×9 array of PV cells. To form a PV panel, PV cells are mounted to a substrate, typically inflexible, such as glass, and also covered by glass to protect the cells. The resulting panels are heavy. Moreover, given the large size of typical PV panels, mounting systems tend to be heavy and complex to assemble.

Disclosed in some embodiments is a mounting system for solar energy collecting panels that has a base assembly having rails securable to an underlying structure. The system further includes panel mountings configured to receive mounting assemblies of the panels for mounting the panels to the rails so that in use each rail has mounted to it multiple panels whilst each panel is mounted to two or more of the rails.

Also disclosed in some embodiments is a solar energy collecting panel that includes a long dimension extending between opposite ends of the panel and a short dimension extending between opposite sides of the panel, the ratio of the long dimension to the short dimension being greater than 3:1. In one form, the ratio is greater than 10:1. Also disclosed is a solar energy collecting system that uses such panels. In a particular form, the panels may be mounted in an array where the individual panels are in generally parallel alignment with respect to their long dimension.

Also disclosed in some embodiments is a mounting system for solar energy collecting panels that have a base assembly securable to an underlying structure, panel mountings for mounting the panels to the base assembly, and a panel support assembly to support the panels in one or more inclined angles relative to the base assembly. In one form, the panel support assembly is a linkage assembly that allows for angular adjustment of the panels relative to the base assembly. In one form, the panel support assembly includes electrical connections that electrically couple the panels to an electrical network.

At least one embodiment of the mounting system has fewer securing points than current systems, and a simplified electrical configuration, such that it can be faster to install than conventional systems. Whilst not limited to such embodiments, it is suited to mounting a solar collector, such as a PV panels to a roof of a building such as a house or commercial building. It can also be arranged to allow for relatively easy change of orientation of the PV panels to track seasonal variation in sun elevation.

In one form, the mounting portion may be a cross bar receivable in a slot in the mounting rails. Orientation supports are able to be fixed between an orientation rail, slidably mounted to the mounting rail, and a portion of the PV panel spaced from the mounting portion.

Also disclosed in some embodiments is a method of mounting solar energy collecting panels to an underlying structure, the method includes fixing rails to the structure, and mounting the panels to the rails, whereby each rail has mounted to it multiple panels and each panel is mounted to two or more of the rails.

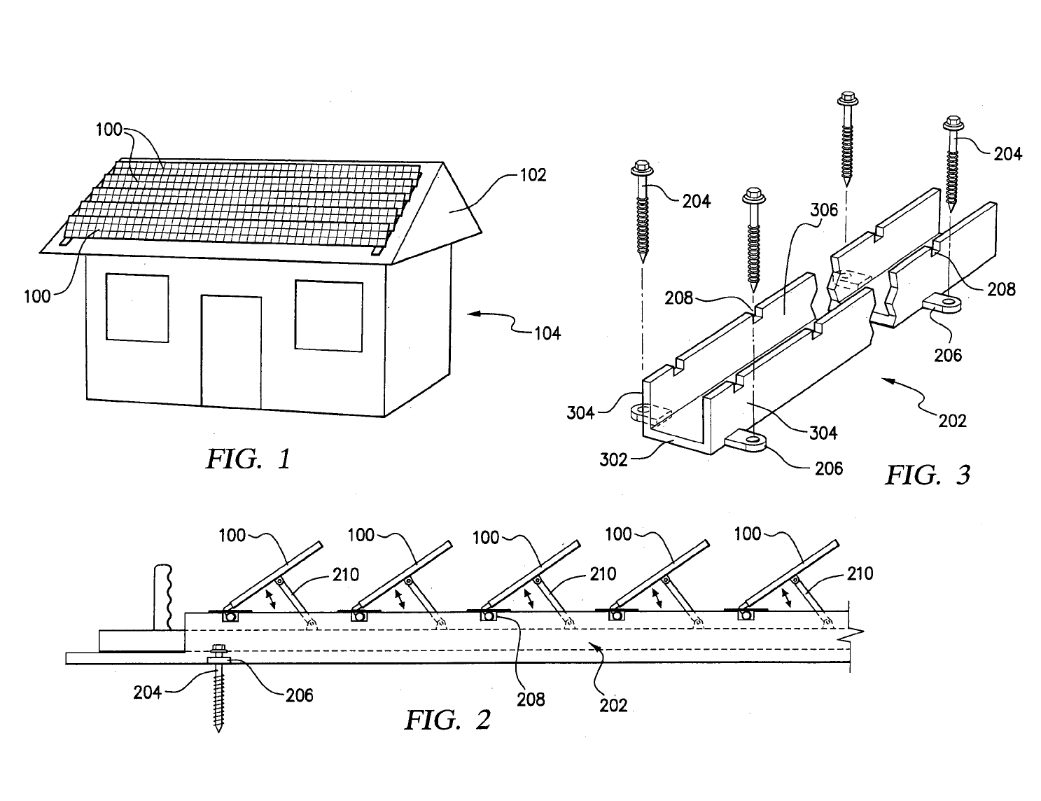

As illustrated in the Figures, some illustrative embodiments of a mounting system for solar collectors, such as PV panels, allows PV panels to be installed faster than with conventional mounting systems. FIG. 1 shows a schematic of a residential building with an illustrative embodiment of a solar collecting system mounted on its roof. As depicted, the system includes multiple PV panels 100 mounted on a roof 102 of a house 104 using, for example, one embodiment of the mounting system (not shown). The PV panels 100 may be coupled to an inverter and the house's energy supply system as per standard systems.

FIG. 2 shows a side elevation of the solar collecting system shown in FIG. 1. The mounting system used to mount the solar collecting system includes a base assembly that is in the form of multiple rails, including rail 202 depicted in FIG. 2. The rail 202 is fixable to the roof 102 by multiple mechanical fasteners 204 (in the illustrated form being screws, such as self drilling Tek screws), but the fastening may be by other means such as by welding, clamps, or may be integrated into the roof structure. In the form as illustrated, the rail 202 is fixed in at least four securing points 206. The other rails (not shown) in the base assembly may be of the same structure as the rail 202 and are mounted in spaced parallel orientation to the rail 202. The rails may be provided in predetermined set lengths or lengths which can be cut to size on site during installation. As will be understood, the securing points 206 are in one form arranged such that they can be fixed to roof rafters underneath the roof covering (e.g., tiles, shingles, roof sheeting, etc).

FIG. 3 shows a schematic of an illustrative embodiment of the mounting rail 202 used in the solar collecting system of FIG. 1. As depicted, the rail 202 is formed from a metal U section, having a base 302 and opposite side walls 304. An open side 306 of the U section rail 202 is opposite the base 302 of the rail 202. The base 302 may closely face the roof 102 or substrate to which the rail 202 is fixed. The rails of the base assembly (including rail 202) may take other forms and by way of example may be formed in a solid or hollow construction. Further, multiple rails may be interconnected, or be integrally formed, so as to constitute a larger frame structure.

The mounting system further includes panel mountings that are configured to receive mounting assemblies of the PV panels 100. As illustrated in FIGS. 2 and 3, the rail 202 includes a series of equi-spaced location portions in the form of slots 208, each slot 208 extending across both side walls 304 of the rail 202. The spacing of the slots 208 may depend on the height of the PV panel 100 to be held by the rails 202, such that if the PV panels 100 are in close facing relationship with the rails 202, the PV panels 100 do not overlap.

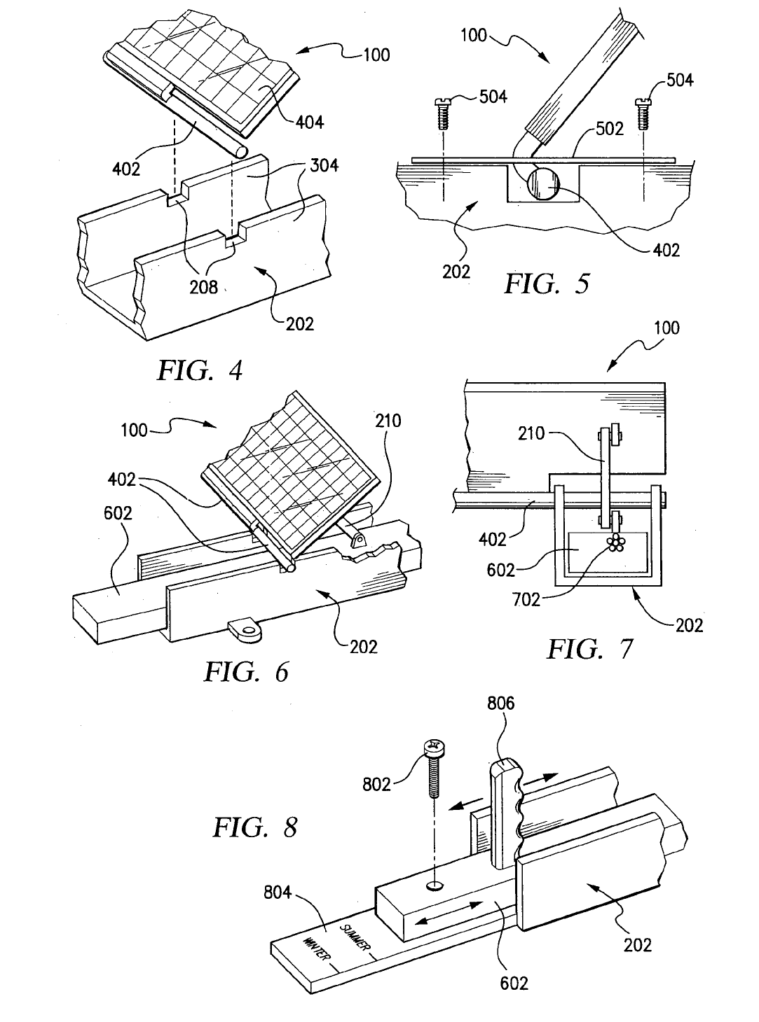

FIG. 4 shows a detailed exploded view of an illustrative embodiment of a connection between the mounting rail 202 and the PV panel 100. As depicted, the slots 208 are configured to receive a PV panel mounting assembly in the form of a bar 402. Each bar 402 is securely fixed in its respective slot 208. In this embodiment, each bar 402 is secured using respective locking plates 502 which are screwed using mechanical fasteners 504 onto one or both side walls 304 of the rail 202 over the slots 208, thus locking in each bar 402, as illustrated in FIG. 5. As will be understood, other fixing mechanisms could be used, such as snap locking arrangements, and so on. Furthermore, the mounting system is arranged to incorporate multiple number of PV panels 100 on multiple rails, where the bar 402 of each PV panel 100 is secured on multiple rails.

Referring to FIGS. 2, 6 and 7, support assembly in the form of orientation posts 210 are employed to maintain the PV panels 100 in a fixed orientation with respect to the roof pitch on which the PV panels 100 are mounted. The orientation posts 210 are connected between respective PV panels 100 and the rails of the base assembly including rail 202. In this embodiment, the orientation posts 210 may also serve to electrically couple the PV panels 100 to an inverter typically employed in solar power systems. In one embodiment, this is achieved by the orientation post 210 having electrical connections at each of its ends, where one end is electrically coupled to a corresponding connector on a particular PV panel 100 and another end is electrically coupled to a corresponding connector on the electrical wiring held within the rail 202.

The mounting system includes fewer physical mounting points than conventional systems. In one embodiment, this is achieved by using lower profile PV panels 100 than conventional PV panels. In this embodiment, the PV panel 100 has a multiple number of approximately 150 mm×150 mm PV cells 404 connected in series in a single row to a substrate, installed in “landscape” orientation. This is in contrast to typical PV panels which have a 2-D array of PV cells, such as 6×9 arrays, which are installed in “portrait” orientation. The aspect ratio (being the length (or long dimension) relative to the height (or short dimension)) of the PV panels 100 is in one form greater than 3:1, and in another form greater than 10:1. The aspect ratio may be even greater (say 50:1) so that the individual panels resemble slats. In one form, the ratio is between 3:1 and 60:1. In one form, the ratio is between 10:1 and 40:1.

The low profile of the PV panel 100 results in reduced wind shear on the PV panel 100 and, thus, the mounting system requires fewer physical connection points. Furthermore, unlike conventional PV panels where the mounting system is separate and must be fixed to the PV panel during installation, the PV panels 100 of the illustrated embodiments have at least part of the mounting (e.g., the bar 402) integrally formed therewith. In alternative arrangements, the PV panel 100 could also have a truss frame supporting the rear of the PV panel 100 to reduce torsional flex from wind shear.

In another embodiment, the orientation or inclination of each PV panel 100 can be changed to accommodate the change in inclination of the sun across the seasons. This can be useful for the following reasons. PV cell output with respect to the sun's angle of incidence can be approximated by a cosine function at sun angles from 0° to 50°. Beyond an incident angle of 50°, the available solar energy falls off rapidly and becomes negligible at approximately 85°. Therefore, it is convenient and sufficient within the normal operating range to model fluctuations in photocurrent verses incident angle using the following equation:

Iₚₕ=Iₘₐₓ COS ⊖

The following example shows the difference between hard-setting the PV angle (as is typical in PV panel installations) compared with having an adjustable angle. Using Melbourne, Australia, as an example, the summer solstice sun inclination from the horizontal is 75°, which reduces to an inclination of 29° at the winter solstice, via an equinox of 52°. Assuming the PV panel is set to 60°, which is typical for flat roof installations in Melbourne at least, the loss of cell potential between summer and winter solstices is as follows:

Loss of cell potential—summer solstice: 3%
Loss of cell potential—equinox: <1%
Loss of cell potential—winter solstice: 14%.

Assuming the PV panels are mounted to a common pitched roof, which is very often the case due to cost and complexity of mounting, the loss of cell potential between summer and winter solstices is as follows:

Loss of cell potential—summer solstice: 0%
Loss of cell potential—equinox: 8%
Loss of cell potential—winter solstice: 31%.

It may not feasible to alter PV panel inclination seasonally using standard roof mounting systems. One reason is the size and weight of typical roof mounted PV panels means that, when mounted to a roof, they are fixed into a set position which cannot be adjusted.

Referring to FIGS. 6 to 8, the illustrated embodiment allows for change of the PV panels 100 inclination. This is achieved using the rail system described above in conjunction with an orientation member 602 slidably mounted within each rail 202. To effect change in inclination, the orientation posts 210 are connected to the orientation member 602 and act as a linkage assembly. Further, the support bars 402 act as a hinge within their slot 208. Therefore, if the orientation member 602 is moved within the rail 202, the inclination of the PV panels 100 that are connected to that orientation member 602 through the posts 210 is changed.

As will be understood, the mounting system can be arranged to allow adjustment to an infinite number of inclinations. However, for practical purposes, the number of inclinations may be two—one for the summer time (set at an angle of incidence between the spring/autumn equinox and summer solstice) and one for the winter time (set at an angle of incidence between the spring/autumn equinox and winter solstice). The mechanism for adjusting the angle of inclination in the embodiment illustrated is manual, where a user loosens a fixing means in the form of a locking screw 802 (which otherwise fixes the orientation member 602 to its rail 202) and slides the orientation member 602 in its rail 202 to the desired location before tightening the locking screw 802 to re-fix the orientation member 602 in place. In this embodiment, indicia 804 may be provided to show the user where to slide the orientation member for a given season (“summer” or “winter”). A handle 806 may be provided on the orientation member 602 for the user to grip to slide the orientation member into the desired position. In an alternative arrangement, change of orientation could be effected differently, for example by pneumatic or hydraulic means. The inclination change could also be automated.

To install the mounting system, multiple rails are first fixed to the roof 102, where the rails are mounted in a spaced parallel relationship. As will be understood, for increased efficiency, the mounting system can be mounted on a portion of roof which faces toward the sun; facing toward north in the southern hemisphere and toward south in the northern hemisphere. The rails are positioned on the roof 102 to run approximately north-south. As mentioned above, the rails may be supplied in a single length or set lengths which can be cut to size on site as required. Once the rails are fixed to the roof 102, orientation member 602 is inserted into one or more of the rails (e.g., rail 202) and secured into position using the locking screw 802. The PV panels 100 are then installed on the rails in parallel relationship to each other, whereby the bars 402 are positioned into respective slots 208 and secured in place by for example the locking plates 502 being fixed to the rail 202 to secure the bars 402 of the PV panels 100 to the rail 202. Respective orientation posts 210 are then secured between each PV panel 100 and the orientation member 602.

The PV panels 100 may then be electrically coupled to an inverter as follows. Firstly, as illustrated in FIG. 7, electrical cabling 702 is provided in one of the orientation members 602. In this embodiment, one electrical cable is provided for each PV panel 100 connection, with a connection point provided near to or at fixing points 704 on the orientation members 602 for the orientation posts 210. Therefore, the PV panels 100 can be electrically connected to their respective cables in the orientation members 602 when connecting the orientation posts 210 to the orientation members 602.

While the above description is concerned with the mounting of PV panels, it will be understood that it is not limited to PV panels. For example, in alternative arrangements, it may be used as a mounting system for solar thermal collectors, such as flat plate thermal collectors, or evacuated solar tube arrays.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). Further, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

It is to be understood that, if any prior art publication is referred to herein, such reference does not constitute an admission that the publication forms a part of the common general knowledge in the art, in Australia or any other country.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods which can, of course, vary. It is also to be understood that the terminology used herein is for the purpose of describing particular embodiments only, and is not intended to be limiting.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A mounting system for mounting a plurality of solar energy collecting panels to an underlying structure, the system comprising:
a base assembly having plurality of rails securable to the underlying structure;
a plurality of mounting assemblies mounted to and extending between two or more of the plurality of rails;
a plurality of solar energy collecting panels mounted to the plurality of mounting assemblies; and
a plurality of support arms connected to one of the plurality of panel mountings and connected to the base assembly, wherein the plurality of support arms are configured to support the one of the plurality of panel mountings at two or more angles with respect to the plurality of rails, and wherein at least one of the plurality of support arms comprises an electrical connection between at least one of the plurality of solar energy collecting panels and an electrical network.

2. The system of claim 1, wherein the plurality of rails include spaced apart receiving formations, wherein the plurality of mounting assemblies are mounted to ones of the receiving formations, and wherein the base assembly further comprises locking members configured to retain the plurality of mounting assemblies in the ones of the receiving formations.

3. The system of claim 2, wherein the locking members are configured to releasably retain the plurality of mounting assemblies in the ones of the receiving formations.

4. The system of claim 2, wherein the receiving formations comprise transverse recesses that open to an upper surface of respective ones of the plurality of rails.

5. The system of claim 4, wherein the locking members comprise plates configured to extend over respective ones of the transverse recesses to retain one or more of the plurality of mounting assemblies in the recesses.

6. The system of claim 1, wherein the plurality of rails comprise profiled metal sections.

7. (canceled)

8. A mounting system for mounting a plurality of solar energy collecting panels to an underlying structure, the system comprising:
a base assembly securable to the underlying structure, the base assembly comprising at least one rail and at least one orientation member slidably mounted within the at least one rail;
a plurality of mounting assemblies pivotably mounted to the base assembly;
a plurality of solar energy collecting panels mounted to the plurality of mounting assemblies; and
a plurality of orientation posts interconnecting respective ones of the plurality of mounting assemblies to the at least one orientation member to support the plurality of mounting assemblies in two or more inclined angles relative to the at least one rail, and wherein at least one of the plurality of orientation posts comprises an electrical connection configured to connect at least one of the plurality of solar energy collecting panels to an electrical network.

9.-11. (canceled)

12. The system of claim 8, wherein movement of the at least one orientation member relative to the at least one rail causes a corresponding movement of the plurality of orientation posts to change the angular orientation of the plurality of mounting assemblies.

13. The system of claim 12, wherein ones of the plurality of orientation posts comprises electrical connections configured to electrically couple the plurality of solar energy collecting panels to the electrical network.

14. The system of claim 8 wherein the plurality of solar energy collecting panels have opposite major surfaces one of which is a solar energy receiving surface, the plurality of solar energy collecting panels having a long dimension extending between opposite ends of the plurality of solar energy collecting panels and a short dimension extending between opposite sides of the plurality of solar energy collecting panels, the ratio of the long dimension to the short dimension being greater than 3:1.

15. The system of claim 14, wherein the ratio of the long dimension to the short dimension is greater than 10:1.

16. (canceled)

17. The system of claim 14, wherein ones of the plurality of mounting assemblies comprise a bar extending along one of the opposite sides of at least one of the plurality of solar energy collecting panels.

18.-21. (canceled)

22. A method of mounting a plurality of solar energy collecting panels to an underlying structure, comprising:
fixing a plurality of rails to the underlying structure, the plurality of rails comprising receiving formations;
placing a plurality of mounting assemblies in the receiving formations of the plurality of rail, wherein the plurality of mounting assemblies extend between two or more of the plurality of rails, wherein plurality of solar energy collecting panels are mounted to the plurality of mounting assemblies; and
connecting a plurality of orientation posts between ones of the plurality of mounting assemblies and at least one orientation member slidably mounted within at least one of the plurality of rails, wherein the plurality of orientation posts are configured to support the plurality of mounting assemblies in two or more inclined angles with respect to the plurality of rails, and wherein at least one of the plurality of orientation posts comprises an electrical connection configured to electrically connect at least one of the plurality of solar energy collecting panels to an electrical network.

23. The method of claim 22, wherein, the receiving formations are formed in the plurality of rails.

24. The method of claim 22, further comprising retaining portions of the plurality of mounting assemblies in the receiving formations of the plurality of rails using releasable locking members.

25. (canceled)

26. The method of claim 22, further comprising electrically coupling the at least one of the plurality of solar energy collecting panels to the electric network via the electrical connection of the at least one of the plurality of orientation posts.

27. The system of claim 1, wherein the plurality of solar energy collecting panels have opposite major surfaces one of which is a solar energy receiving surface, the plurality of solar energy collecting panels having a long dimension extending between opposite ends of the plurality of solar energy collecting panels and a short dimension extending between opposite sides of the plurality of solar energy collecting panels, the ratio of the long dimension to the short dimension being greater than 3:1.

28. The system of claim 27, wherein the ratio of the long dimension to the short dimension is greater than 10:1.

29. The method of claim 22, wherein the plurality of solar energy collecting panels have opposite major surfaces one of which is a solar energy receiving surface, the plurality of solar energy collecting panels having a long dimension extending between opposite ends of the plurality of solar energy collecting panels and a short dimension extending between opposite sides of the plurality of solar energy collecting panels, the ratio of the long dimension to the short dimension being greater than 3:1.

30. The method of claim 29, wherein the ratio of the long dimension to the short dimension is greater than 10:1.
